(19) United States
(12) Patent Application Publication
(10) Pub. No.: US 2013/0177173 A1
(43) Pub. Date: Jul. 11, 2013

(54) System and Method for Controlling Volume in Audio/Listening Devices

(71) Applicant: IGo, Inc., Scottsdale, AZ (US)

(72) Inventors: Eljay Driessens, San Francisco, CA (US); Phil Johnson, San Francisco, CA (US); Garry DuBose, Scottsdale, AZ (US)

(73) Assignee: IGO, INC., Scottsdale, AZ (US)

(21) Appl. No.: 13/738,623

(22) Filed: Jan. 10, 2013

Related U.S. Application Data
(60) Provisional application No. 61/585,223, filed on Jan. 10, 2012.

(51) Int. Cl. H03G 1/00

(52) U.S. Cl. CPC H03G 1/00
USPC 381/107

(57) ABSTRACT

A system and method for automatically limiting or otherwise controlling the volume level within audio devices is provided. A sound level controlled amplification system is configured to sample audio signals for an audio device, and if above a predetermined limit, de-amplify the volume level to a safer level of sound, and control and maintain such safe level until the sample audio signal is within the predetermined limit of safe sound.

### CROSS-REFERENCE TO RELATED APPLICATIONS

This application is a non-provisional of U.S. Provisional Application No. 61/585,223, entitled “SYSTEM AND METHOD FOR CONTROLLING VOLUME IN AUDIO/LISTENING DEVICES,” which was filed on Jan. 10, 2012, and is hereby incorporated by reference for any purpose in its entirety.

### FIELD OF INVENTION

The present invention relates to volume control in audio devices. More particularly. the present invention relates to a system and method for automatically limiting or otherwise controlling the volume level within audio devices.

### BACKGROUND OF THE INVENTION

With the increased proliferation of mobile audio players and devices, such as MP3 players, DVD players, cell phones, PDAs and the like, more and more consumers, and in particular children, are using such devices for video/audio entertainment. While in many instances parental control over the volume levels is exercised, it is still quite possible for safe audio levels, e.g., below 85 dB or otherwise the level of volume before potential damage occurs or is otherwise deemed harmful for children, to be well exceeded. Unfortunately, even smaller durations of excessive noise levels can cause sustained and potentially permanent damage to hearing capabilities, particularly in young children.

Such excessive noise levels can be caused not only by improper volume control settings, but also in differences in sound amplification from different audio recordings. For example, in connection with songs downloaded onto portable electronics, such as MP3 or cell phones, it is not uncommon for one song to have a safe level of volume and then the subsequent song have a materially higher volume that is amplified well above the acceptably safe threshold level. Thus, manually adjusting the current volume controls to a perceived “safe” level or one song may not be sufficient to prevent harm when a subsequent song “plays” at a much higher decibel level.

### SUMMARY OF THE INVENTION

In accordance with various aspects, the system and method for automatically limiting or otherwise controlling the volume level within audio devices comprises a sound level controlled amplification system. The sound level controlled amplification system is configured to sample audio signals for an audio device, and if above a predetermined limit, de-amplify the volume level to a safer level of sound, and control and maintain such safe level until the sample audio signal is within the predetermined limit of safe sound.

In accordance with an exemplary embodiment, the controlled amplification system comprises a sampling circuit and a sound limiter control circuit. The sampling circuit samples the audio signal at a specified sample rate. If the signal goes beyond a selected or predetermined limit, e.g., the level of volume before potential damage occurs or is otherwise deemed unsafe for children, the sound limiter control circuit within the controlled amplification system automatically reduces the present amplification level to a lower, safer level. The sound limiter control circuit will maintain the lower amplification state or level until the actual audio signal decreases to within the selected or predetermined limit, then the sound limiter control circuit will no longer control, while the sampling circuit will continue to monitor. In the event the volume on the audio device is again increased above the selected or predetermined limit, then the controlled amplification system will again de-amplify the volume of sound.

In accordance with various exemplary embodiments, the de-amplification level is calculated based on the sampled sound level and the selected or predetermined limit, and thus can range greatly. In addition, the sampling rate can be suitably varied depending on a number of factors.

### BRIEF DESCRIPTION OF THE DRAWINGS

A more complete understanding of the present invention may be derived by referring to the detailed description when considered in connection with the Figures, where like reference numbers refer to similar elements throughout the Figures, and:

FIG. 1 illustrates a block diagram of an exemplary controlled amplification system;

FIGS. 2A and 2B illustrates a block diagram and a block diagram/element representation of a sampling circuit and a sound limiter control circuit in accordance with an exemplary embodiment; and

FIG. 3 illustrates a circuit diagram of an exemplary controlled amplification system in accordance with an exemplary embodiment.

### DETAILED DESCRIPTION OF EXEMPLARY EMBODIMENTS OF THE INVENTION

The present invention may be described herein in terms of various functional components and various processing steps. It should be appreciated that such functional components may be realized by any number of hardware or structural components configured to perform the specified functions. For example, the present invention may employ various integrated components, such as amplifiers, current sensors, and logic devices comprised of various electrical devices, e.g., resistors, transistors, capacitors, diodes and the like, whose values may be suitably configured for various intended purposes. In addition, the present invention may be practiced in any integrated circuit application. However for purposes of illustration only, exemplary embodiments of the present invention will be described herein in connection with a system and method for use with volume control of audio devices. Further, it should be noted that while various components may be suitably coupled or connected to other components within exemplary circuits, such connections and couplings can be realized by direct connection between components, or by connection through other components and devices located thereinbetween.

In accordance with various aspects, the system and method for automatically limiting or otherwise controlling the volume level within audio devices comprises a sound level controlled amplification system. The sound level controlled amplification system is configured to sample audio signals for an audio device, and if above a predetermined limit, de-amplify the volume level to a safer level of sound, and control and maintain such safe level until the sample audio signal is within the predetermined limit of safe sound.

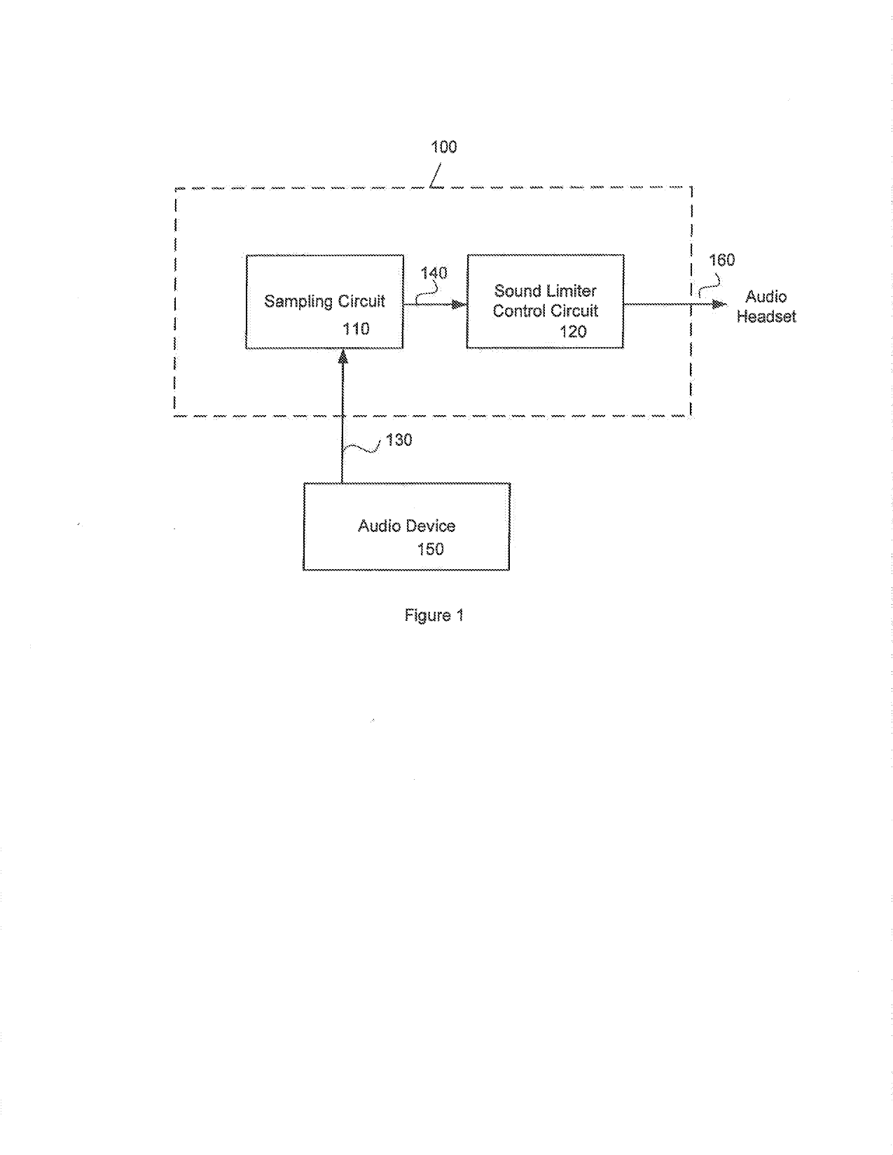

In accordance with an exemplary embodiment, with reference to FIG. 1, an exemplary controlled amplification system 100 comprises a sampling circuit 110 and a sound limiter control circuit 120. Sampling circuit 110 is configured to sample an audio signal 130 from an audio device 150 at a specified sample rate and provide an output signal 140 that represents the sampled signal. Audio device 150 can comprise various devices for providing audio to listeners, from stationary stereo players to mobile audio players and devices and the like, such as MP3 players, DVD players, cell phones, PDAs and other similar audio devices. Sound limiter control circuit 120 is configured to receive output signal 140, and depending on the level of audio sampled from audio device 150, provide a controlled amplified output signal 160 to a listening headset or listening device, such as headphones, earphones, ear buds, and the like.

Sound level controlled amplification system 100 can be suitably coupled to an existing listening headset or like device (between such headset/listening device and the audio device), or can be suitably integrated within the headset or like device. The latter can be more preferable so as to not have a child disable the sound limiting control from the headset or listening device.

During operation, if the sampled signal generated by sampling circuit 110 goes beyond a selected or predetermined limit, e.g., 85 dB or otherwise a level of volume before potential damage occurs or is otherwise deemed unsafe for children, as determined by sound limiter control circuit 120 in monitoring output signal 140, sound limiter control circuit 120 automatically reduces the present amplification level to a lower, safer level and provides de-amplified output signal 160. Sound limiter control circuit 120 will maintain the lower amplification state or level until the actual audio signal (or sampled rate) decreases to within the selected or predetermined limit, then sound limiter control circuit 120 will no longer limit the volume of sound provided to audio signal 160. Meanwhile, sampling circuit 110 will continue to sample audio output 130. In the event the volume on the audio device again increases above the selected or predetermined limit, then controlled amplification system 100 will again automatically control the volume of sound by having sound limiter control circuit 120 suitably de-amplify the volume of sound at output signal 160 to the safe, lower level.

In addition, the sampling rate can be suitably varied depending on a number of factors. In an exemplary embodiment, the sampling rate is about 2.5 seconds; however, increased or decreased sampling rates can also be used. For example, if the input audio that is sampled and determined to be fairly constant in level over time, a lower sampling rate can be used. This lower rate will tend to suppress “breathing” side effects wherein the audio level at the output 160 will appear to swell and shrink in volume at a fast rate. With non-dynamic audio passages this effect is most noticeable. On the other hand, for input audio that is sampled and determined to be dynamic in nature and varying quickly in level, the sampling rate can be increased to allow sudden peaks to be controlled quickly. In this scenario with dynamic audio, the change in volume at output 160 is not noticed as “breathing” since the audio signal already has a wide variance.

The sampling rate can also be used to determine the sampled sound level to provide an average sampled sound level at output signal 140 to sound limiter control circuit 120, wherein control circuit 120 can then compare the average sampled sound level to a predetermined threshold or predetermined sound level. Such a sample can take into account two or more sampled signals to provide the average sampled signal, or can take the running average of “X”-number of sampled signals. In accordance with other exemplary embodiments, sampling circuit 110 can suitably provide an output signal 140 corresponding to each sampled audio signal, such that if the volume level of audio device 150 at any one time exceeds the predetermined safe level, then that audio signal can be suitably limited by sound limiter control circuit 120 before providing an output signal 160 to the listening headset.

In accordance with various exemplary embodiments, the de-amplification level is calculated based on the sampled sound level and the selected or predetermined limit, and can range at different de-amplified levels. For example, the de-amplification level can be set at the predetermined limit, or in an abundance of caution, can be set at approximately 95%, 90% or other levels lower than the predetermined limit.

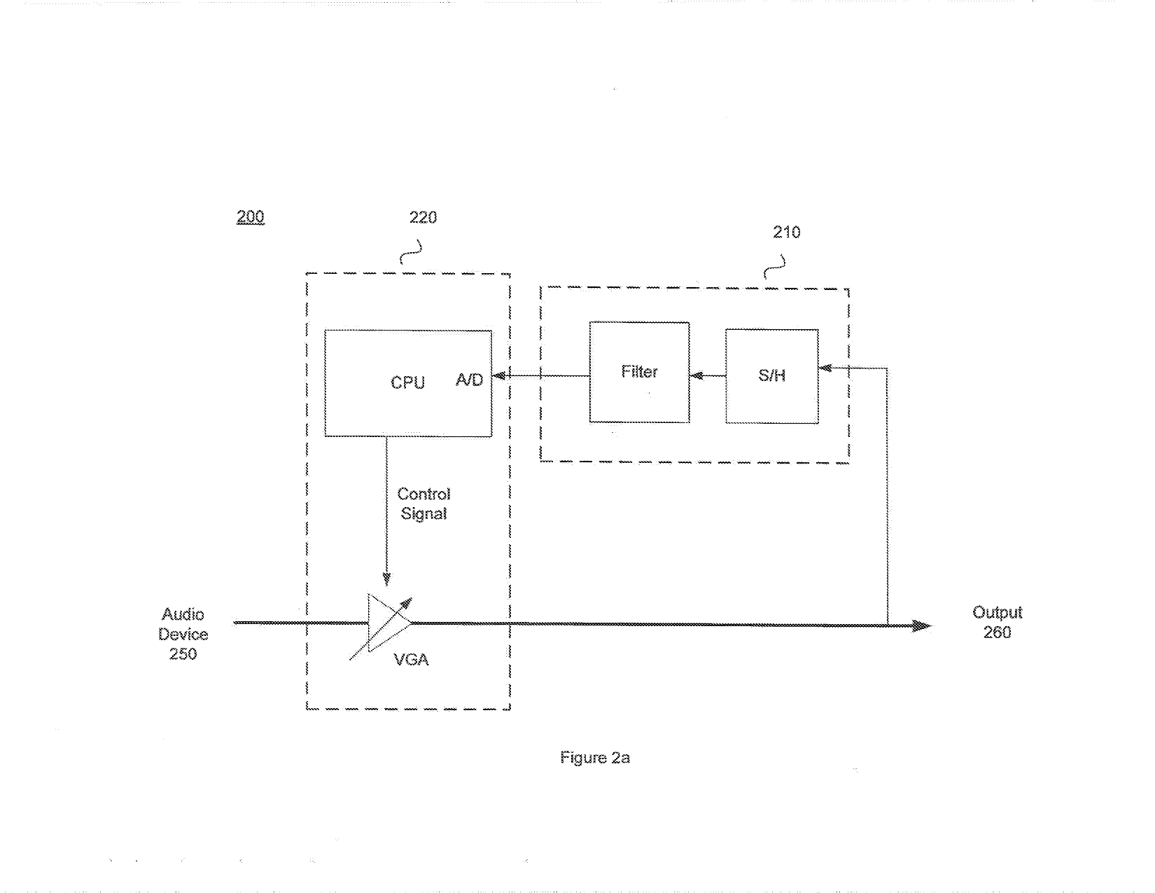

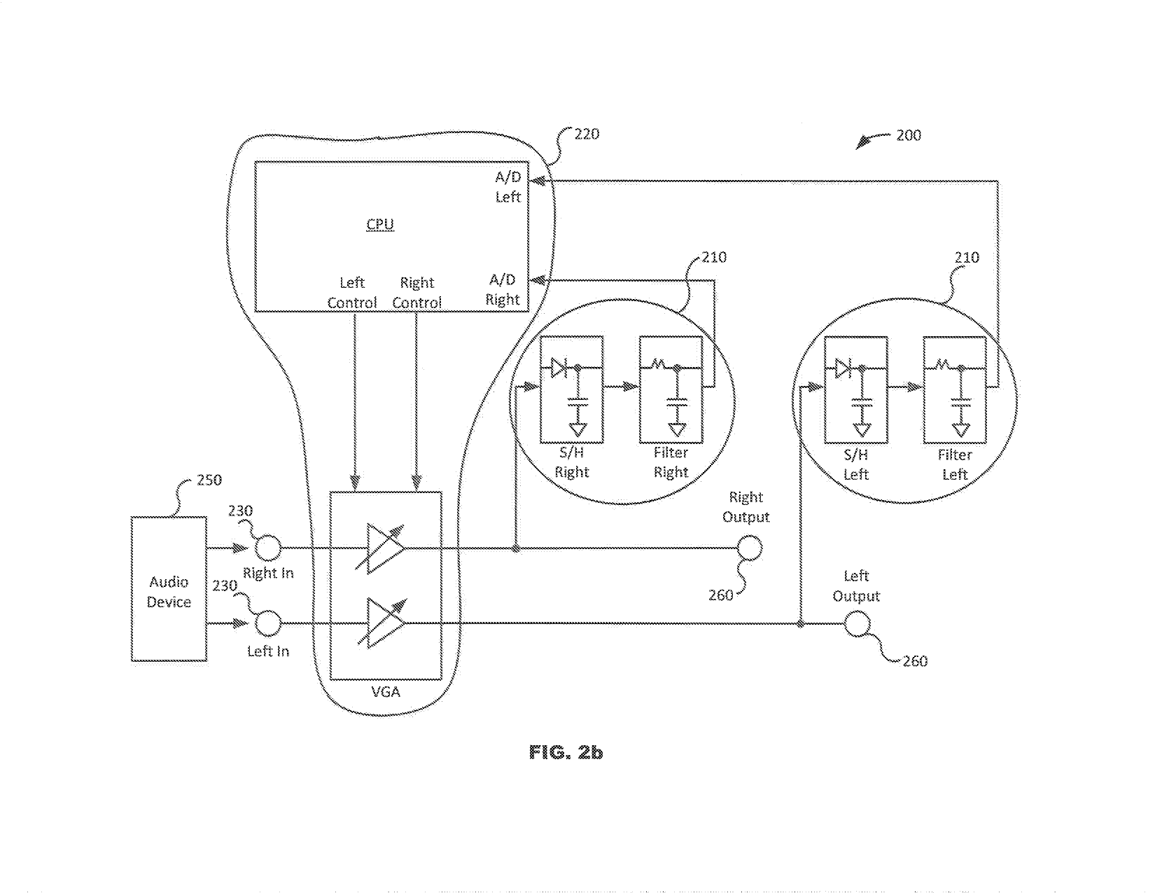

Sampling circuit 110 and sound limiter control circuit 120 can comprise various configurations for sampling audio device 150 and providing a controlled output signal 160. For example, with reference to FIGS. 2A and 2B, a block diagram illustrates an exemplary controlled amplification system 200 comprising sampling circuits 210 and a sound limiter control circuit 220 arranged for two channels of stereo audio.

Sampling circuit 210 comprises a first sample and hold circuit (S/H) whose input is coupled to an audio output 260. The S/H circuit may be a simple rectifier/hold capacitor, or may be implemented using an electronic switch and hold capacitor, or any other configuration for providing sample and hold circuit functionality as appreciated in the electronic industry. The output of the S/H circuit can be suitably passed to a further smoothing filter that serves to provide a mostly DC signal, and which can comprise various configurations. This smoothed DC signal is then provided to sound limiter control circuit 220, for example, by coupling to an Analog to Digital Converter (ADC) input located in sound limiter control circuit 220.

In various embodiments, sound limiter control circuit 220 is composed of a Variable Gain Amplifier (hereafter referred to as VGA), and a Central Processor Unit (hereafter referred to as CPU). In various embodiments, controlled amplification system 200 further comprises VGA inputs 230 received from an audio device 250, which may be processed by the VGA of sound limiter control circuit 220 to provide either an amplified or de-amplified output signal that is received by sampling circuit 210. The output signal of the VGA of sound limiter control circuit 220 is also passed directly to the outputs 260 that couple to the listening headset. The CPU of sound limiter control circuit 220 receives the sampled and smoothed outputs from sampling circuit 210 into the CPU Analog to Digital Converter inputs. Based on the value of the DC signal at the CPU A/D converter input, which is proportional to the output sound level from the VGA, the CPU will selectively increase or decrease the gain of the VGA and hence the output audio level at 260.

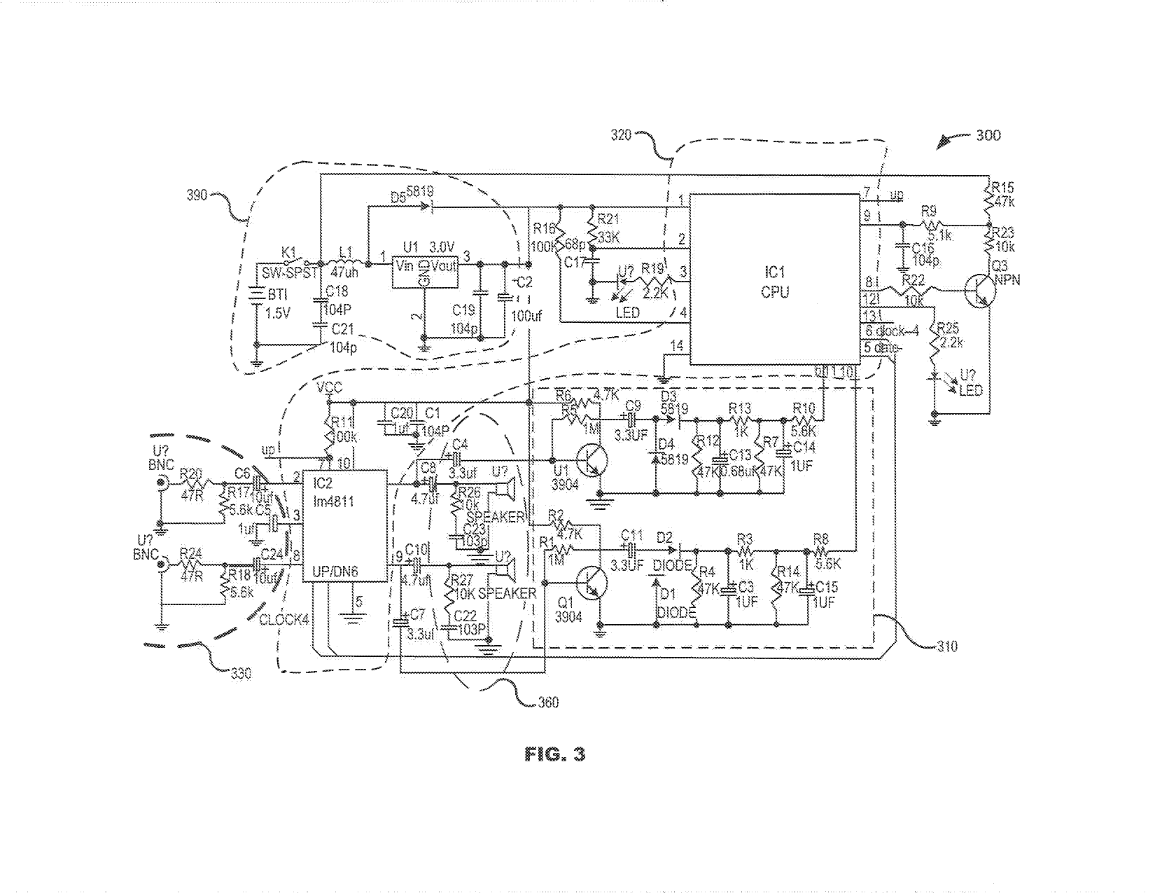

With reference to FIG. 3, an exemplary circuit diagram for a controlled amplification system 300 is illustrated in accordance with an exemplary embodiment. It should be noted however, that the circuit shown is simply for illustration purposes, and the various other circuit configurations for performing the intended functions can be suitably utilized.

Controlled amplification system 300 may comprise a sampling circuit 310 and a sound limiter control circuit 320. Signal inputs from the audio device 150 are received at inputs 330 and coupled to the sound limiter control circuit 320, composed of a VGA (IC2) and a CPU (IC1). The outputs of the VGA are coupled both to the sampling circuit 310 and outputs 360. The output of sampling circuit 310 is a DC signal sent to the sound limiter control circuit 320 that is proportional to the audio sound level coupled to outputs 360. A power circuit 390 of controlled amplification system 300 provides regulated DC for sound limiter 320 and sampling circuit 310. The power source in power circuit 390 may come from a battery BT1, as shown, or may also be from an external DC or AC source. A first indicator circuit 380 may provide a visual indication by LED that the power is on and within acceptable limits, and also provides a measurement of the system input DC voltage to the CPU by way of transistor Q3 and associated resistors. A second indicator circuit 370 may provide an indication that the output audio level is being controlled within an acceptable range.

Within the sound limiter circuit 320, the audio level control is implemented as an integrated dual channel Variable Gain Amplifier (IC2) with a 2 wire digital control interface. This control interface is connected back to the CPU and allows the CPU to vary the gain or loss in the VGA over a range of −45 dB to +12 dB in 3 dB steps. These small steps and wide range allow the audio level to be controlled subtly without sudden jumps in amplitude. The VGA has sufficient output drive capability to couple directly through outputs 360 to small speakers as may be found in ear buds or headphones.

Sampling circuit 310 receives its inputs from the VGA outputs and for each channel right and left a buffer transistor is used to isolate and amplify the audio signal. The amplified signals are coupled through a capacitor (C9/C11) and diodes (D3 and D4/D1 and D2) to a second capacitor (C13/C3). The first capacitor and diodes serve as a half wave rectifier to establish a positive AC voltage. The series diode (D3/D2) and second capacitor (C13/C3) serve as a peak detector so the highest DC voltage is stored on the second capacitor. The following series resistor (R13/R3) and third capacitor (C14/C15) smooth the moving DC voltage before it is applied to the input of the Analog to Digital Converter (ADC) located on the CPU. The smoothed DC voltage is used by the CPU to decide if the audio signal passing to the outputs 360 is within acceptable limits. If the signal is too large, the 2 wire digital control interface from the CPU will instruct the VGA to reduce its gain by a sufficient number of steps to bring the audio signal back into an acceptable range. If the audio signal is not greater than the acceptable limit, the gain of the VGA is stepped back toward 0 db (no gain reduction).

The present invention has been described above with reference to various exemplary embodiments. However, those skilled in the art will recognize that changes and modifications may be made to the exemplary embodiments without departing from the scope of the present invention. For example, the various exemplary embodiments can be implemented with other types of sampling and control circuits in addition to the circuits illustrated above. Alternatively, the sampling of audio signals while shown being effected after the amplification of the VGA, may be sampled before the VGA in another embodiment. These alternatives can be suitably selected depending upon the particular application or in consideration of any number of factors associated with the operation of the system. Moreover, these and other changes or modifications are intended to be included within the scope of the present invention.

1. A system for automatically limiting or otherwise controlling the volume level within audio devices, said system comprising:
a sound level controlled amplification system configured to sample audio signals from an audio device, and if above a predetermined limit, de-amplify the volume level to a safer level of sound, and control and maintain such safe level until the sample audio signal is within the predetermined limit of safe sound;
a headset for playing audio, said headset configured to receive such controlled safe level of sound from said sound level controlled amplification system.

2. The system of claim 1, wherein the sound level controlled amplification system comprises a sampling circuit configured to sample the audio signals from the audio device, and facilitate determination whether the audio signal is above a predetermined limit, and a sound limiter control circuit configured to de-amplify the volume level to a safer level of sound, and control and maintain such safe level until the sample audio signal is within the predetermined limit of safe sound.

3. A method for automatically limiting or otherwise controlling the volume level within audio devices, said method comprising:
sampling audio signals from an audio device;
determining if the sampled audio signals are above a predetermined limit;
de-amplifying the volume level to a safer level of sound if above said predetermined limit; and
controlling and maintaining such safe level until the sampled audio signal is within the predetermined limit of safe sound.
